(19) United States
(12) Patent Application Publication
(10) Pub. No.: US 2011/0132456 A1
(43) Pub. Date: Jun. 9, 2011

(54) SOLAR CELL INTEGRATING MONOCRYSTALLINE SILICON AND SILICON-GERMANIUM FILM

(76) Inventors: Jian-Yang LIN, Yunlin County (TW); Pai-Yu Chang, Yunlin County (TW); Tsong-Hsueh Wu, Yunlin County (TW)

(21) Appl. No.: 12/632,311

(22) Filed: Dec. 7, 2009

(51) Int. Cl. H01L 31/00

(52) U.S. Cl. 136/258

(57) ABSTRACT

The present invention discloses a solar cell integrating monocrystalline silicon and a SiGe film, which comprises an N-type amorphous silicon-germanium (SiGe) film formed on a P-type monocrystalline silicon substrate. The P-type monocrystalline silicon substrate has a roughened surface to capture sunlight. A transparent conductive layer is stacked on the N-type amorphous SiGe film. Metal electrodes are formed on the transparent conductive layer and penetrate the transparent conductive layer to contact the N-type amorphous SiGe film. A P-type polycrystalline SiGe film is formed on the backside of the P-type monocrystalline silicon substrate. A back surface field is arranged below the P-type polycrystalline SiGe film to prevent from the recombination of major carriers. A backside metal electrode layer is arranged below the back surface field to function as a backside electrode and decrease the contact resistance. Thereby, the present invention can effectively promote the absorption rate of solar energy.

### FIELD OF THE INVENTION

The present invention relates to a solar cell, particularly to a solar cell integrating monocrystalline silicon and a SiGe film.

### BACKGROUND OF THE INVENTION

The solar cell is a device converting solar energy into electric energy. Unlike ordinary cells, the solar cell does not transmit conductive ion by electrolyte but acquires electric potential from the PN junction of the P-type and N-type semiconductors. When illuminated by sunlight, the semiconductor generates a great number of free electrons. The negative charged electrons move to the N-type semiconductor. The movement of electrons forms current, and an electric potential difference is created in the PN junction to form storable electric energy.

The solar cell made of monocrystalline silicon has the highest energy conversion efficiency and a longer service life. Monocrystalline silicon solar cell is grown with the Czochralski method from a silicon material having a purity of 99.999999999% (totally eleven “9”s) in a quartz crucible. The solar cell made of monocrystalline silicon is stable and has a high efficiency of 12-24% in commercially-available products.

The solar cell made of amorphous silicon is also a mass-fabricated product, which has the lowest price and the highest productivity and is extensively used in consumer electronic products. However, the amorphous-silicon solar cell is problematic in absorbing sunlight energy. The amorphous silicon has an energy gap of 1.75-1.8 eV and thus can only absorb the sunlight having wavelengths of below 700 nm. Nevertheless, a considerable portion of the sunlight spectrum falls in the wavelength range of over 700 nm. In fact, increasing the sunlight absorption range is a problem that the related manufacturers are eager to overcome.

### SUMMARY OF THE INVENTION

One objective of the present invention is to provide a solar cell integrating monocrystalline silicon and a SiGe (silicon-germanium) film, which has a higher sunlight absorption rate.

To achieve the abovementioned objective, the present invention proposes a solar cell integrating monocrystalline silicon and a SiGe film, which comprises a P-type monocrystalline silicon substrate, an N-type amorphous SiGe film, a transparent conductive layer, a plurality of metal electrodes, a back surface field, and a backside metal electrode layer. The P-type monocrystalline silicon substrate has an upper surface and a lower surface. The N-type amorphous SiGe film is formed on the upper surface of the P-type monocrystalline silicon substrate. The transparent conductive layer is stacked on the N-type amorphous SiGe film. The metal electrodes are formed on the transparent conductive layer and penetrate the transparent conductive layer to contact the N-type amorphous SiGe film. The back surface field is arranged on the lower surface of the P-type monocrystalline silicon substrate, and the backside metal electrode layer is arranged below the back surface field.

Via the abovementioned technical measure, the solar cell integrating monocrystalline silicon and the SiGe film of the present invention has the following advantages:

1. The amorphous SiGe film has an energy gap Eg (a-SiGe) of 1.0-1.7 eV, which is greater than that of the monocrystalline silicon in the conventional technology, and thus can absorb sunlight having shorter wavelengths. The solar cell of the present invention integrating the N-type amorphous SiGe film and P-type monocrystalline silicon substrate can promote the energy conversion efficiency of the solar cell and reduce the cost of solar cells.

2. The roughened transparent conductive layer can increase the capability of capturing sunlight; the back surface field and the backside metal electrode layer can increase the efficiency of collecting the minority of carriers; further, the backside metal electrode layer arranged below the back surface field can function as the backside electrode and lower the contact resistance.

### BRIEF DESCRIPTION OF THE DRAWINGS

FIG. 1 is a diagram schematically showing the structure of a solar cell integrating monocrystalline silicon and a SiGe film according to one embodiment of the present invention; and

FIG. 2 is a diagram schematically showing the structure of a solar cell integrating monocrystalline silicon and a SiGe film according to another embodiment of the present invention.

### DETAILED DESCRIPTION OF THE PREFERRED EMBODIMENTS

The technical contents of the present invention are described in detail with the embodiments. However, it should be understood that the embodiments are only to exemplify the present invention but not to limit the scope of the present invention.

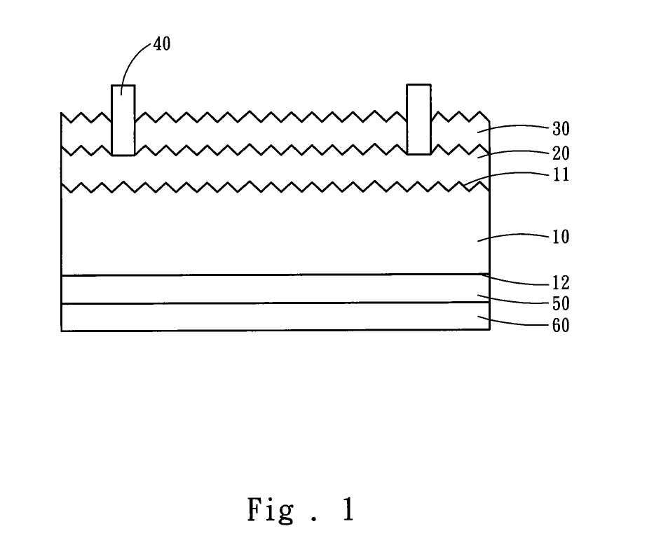

Refer to FIG. 1 a diagram schematically showing the structure of a solar cell integrating monocrystalline silicon and a SiGe film according to one embodiment of the present invention. The solar cell integrating monocrystalline silicon and the SiGe film of the present invention comprises a P-type monocrystalline silicon substrate 10, an N-type amorphous SiGe film 20, a transparent conductive layer 30, a plurality of metal electrodes 40, a back surface field 50, and a backside metal electrode layer 60. The P-type monocrystalline silicon substrate 10 has an upper surface 11 and a lower surface 12. The N-type amorphous SiGe film 20 is formed on the upper surface 11 of the P-type monocrystalline silicon substrate 10 and has a thickness of 0.5-2 μm. The upper surface 11 is a roughened surface. The transparent conductive layer 30 is stacked on the N-type amorphous SiGe film 20. The transparent conductive layer 30 is an anti-reflection transparent conductive layer made of tin indium oxide or zinc oxide.

The metal electrodes 40 are formed on the transparent conductive layer 30 and penetrate the transparent conductive layer 30 to contact the N-type amorphous SiGe film 20. The metal electrodes 40 are alternately arranged to have a form of mutually interposed fingers. The back surface field 50 is arranged on the lower surface 12 of the P-type monocrystalline silicon substrate 10, and the backside metal electrode layer 60 is arranged below the back surface field 50.

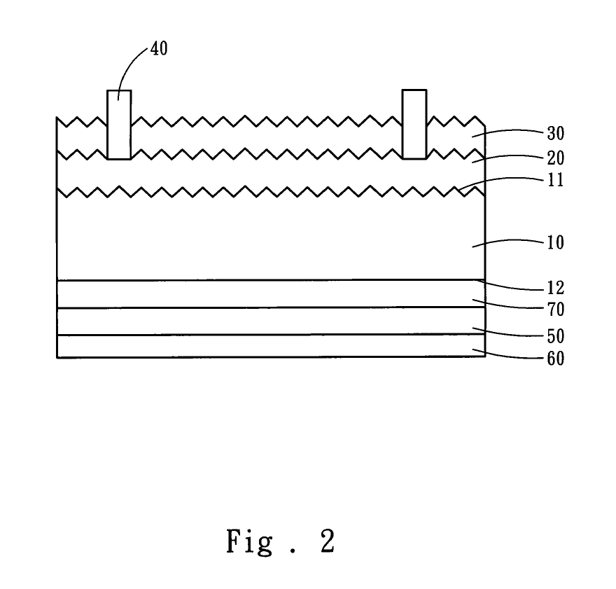

Refer to FIG. 2 a diagram schematically showing the structure of a solar cell integrating monocrystalline silicon and a SiGe film according to another embodiment of the present invention. In this embodiment, the present invention further comprises a P-type polycrystalline SiGe film 70 interposed between the P-type monocrystalline silicon substrate 10 and the back surface field 50. The P-type polycrystalline SiGe film 70 has a thickness of 1-10 μm. The P-type polycrystalline SiGe film 70 has an energy gap smaller than that of the conventional monocrystalline silicon. Thereby, the present invention has diversified energy gaps and higher energy conversion efficiency.

The present invention has the following characteristics:

1. The surface of the transparent conductive layer 30 is roughened to increase the capability of capturing sunlight.

2. The back surface field 50 and backside metal electrode layer 60 can promote the efficiency of collecting minority of carriers, and the backside metal electrode layer 60 is arranged below the back surface field 50 to decrease the resistance.

3. The conventional amorphous SiGe film has an energy gap Eg (a-SiGe) of 1.0-1.7 eV, which is greater than that of the monocrystalline silicon, and thus can absorb sunlight having shorter wavelengths. The P-type polycrystalline SiGe film 70 can absorb sunlight having longer wavelengths. In one embodiment, the P-type polycrystalline SiGe film 70 is arranged on the lower surface 12 of the P-type monocrystalline silicon substrate 10. Via the integration of the P-type monocrystalline silicon substrate 10 with the N-type amorphous SiGe film 20 and/or the P-type polycrystalline SiGe film 70, the present invention greatly promote the energy conversion efficiency of sunlight having different wavelengths.

Because the present invention has a simpler fabrication process, it can provide a low-cost solar cell. Further, the present invention can absorb different bands of the sunlight spectrum and greatly promote the energy conversion efficiency. Thereby, the solar energy can be more extensively applied to homes and industries.

What is claimed is:

1. A solar cell integrating monocrystalline silicon and a silicon-germanium film, comprising:
a P-type monocrystalline silicon substrate having an upper surface and a lower surface;
an N-type amorphous silicon-germanium (SiGe) film formed on said upper surface of said P-type monocrystalline silicon substrate;
a transparent conductive layer stacked on said N-type amorphous SiGe film;
a plurality of metal electrodes formed on said transparent conductive layer and penetrating said transparent conductive layer to contact said N-type amorphous SiGe film;
a back surface field arranged on said lower surface of said P-type monocrystalline silicon substrate; and
a backside metal electrode layer arranged below said back surface field.

2. The solar cell integrating monocrystalline silicon and a silicon-germanium film according to claim 1, wherein said upper surface of said P-type monocrystalline silicon substrate is a roughened surface.

3. The solar cell integrating monocrystalline silicon and a silicon-germanium film according to claim 1, wherein said metal electrodes are formed on said transparent conductive layer and penetrate said transparent conductive layer to contact said N-type amorphous SiGe film; said metal electrodes are alternately arranged to have a form of mutually interposed fingers.

4. The solar cell integrating monocrystalline silicon and a silicon-germanium film according to claim 1, wherein said N-type amorphous SiGe film has a thickness of 0.5-2 μm.

5. The solar cell integrating monocrystalline silicon and a silicon-germanium film according to claim 1, wherein said transparent conductive layer is an anti-reflection transparent conductive layer which is made of a material selected from a group consisting of tin indium oxide and zinc oxide.

6. The solar cell integrating monocrystalline silicon and a silicon-germanium film according to claim 1 further comprises a P-type polycrystalline SiGe film interposed between said P-type monocrystalline silicon substrate and said back surface field.

7. The solar cell integrating monocrystalline silicon and a silicon-germanium film according to claim 6, wherein said P-type polycrystalline SiGe film has a thickness of 1-10 μm.
